(19) United States
(12) Patent Application Publication
(10) Pub. No.: US 2024/0388118 A1
(43) Pub. Date: Nov. 21, 2024

(54) PRE-CHARGE SWITCH DEVICE AND FUEL CELL DEVICE FOR A DAMPED VOLTAGE AND CURRENT ADJUSTMENT, COMPRISING A BATTERY WHICH IS CONNECTED IN PARALLEL, AND MOTOR VEHICLE

(71) Applicant: STACK Hydrogen Solutions GmbH, Aachen (DE)

(72) Inventor: David VERGOSSEN, Gangelt (DE)

(21) Appl. No.: 18/691,514

(22) PCT Filed: Sep. 14, 2022
(86) PCT No.: PCT/EP2022/075494

§ 371 Date: Mar. 13, 2024

(30) Foreign Application Priority Data
Sep. 14, 2021 (DE) 10 2021 123 773.4

(51) Int. Cl. H02J 7/34; B60L 58/40; H01M 8/04537; H01M 8/04858; H01M 10/42; H01M 16/00

(52) U.S. Cl. CPC H02J 7/34; H01M 8/04589; H01M 8/0488; H01M 8/04888; H01M 10/425; H01M 16/006; B60L 58/40; H01M 2220/20; H01M 2250/20; H02J 2300/30

(57) ABSTRACT

The invention relates to a pre-charging switching device and a fuel cell device for automatically adjusting an output voltage of a fuel cell system and a battery voltage of a battery connected in parallel with respect to a load without a DC-to-DC converter connected therebetween. The invention further relates to a motor vehicle equipped therewith. The pre-charging switching device comprises an input connection for connecting the fuel cell system, an output connection for connecting to the battery and the load and an adjustment switching unit connected therebetween. The adjustment switching unit has a controllable limiting element and a regulating device coupled thereto and is configured for damped adjustment of the voltages by regulating a direct current carrying behavior of the limiting element depending on a fuel cell system current detected on the input side.

The present invention relates to a pre-charging switching device for a damped voltage adjustment between a fuel cell system and a battery connected in parallel thereto, a corresponding fuel cell device and a motor vehicle equipped therewith.

In many areas, such as vehicle and drive technology, there is increasing emphasis on electric drives and electrification in general. Batteries, for example, are deployed for this purpose. These are typically composed of a large number of individual battery cells in order to generate a sufficiently high voltage. However, this comes with the risk that individual battery cells may fail, which can have an impact on the functionality or voltage level of the entire battery. However, corresponding measures, such as voltage adaptations or the like, can be complex and cost-intensive and can in turn represent further sources of error. Hybrid systems are also known in which several energy sources are combined with one another. However, this can often require costly, extensive and complex adaptation of the subsystems to one another and in certain situations it can be difficult to achieve efficient and effective interaction between the subsystems. For example, energy consumption in a motor vehicle can be highly dynamic, i.e., change quickly and to a large extent. Such requirements cannot be met by fuel cells, for example, without considerable effort. Therefore, a buffer battery can be used, which, however, typically has to be coupled to the fuel cell via an extensive and complex DC-to-DC converter and can also provide different voltages depending on its state of charge and/or place varying demands on an energy source for charging, which, overall, makes corresponding systems challenging.

In other contexts, intermediate circuits, for example, are used in complex electrical systems. A pre-charging circuit can then be used there, as described, for example, in DE 10 2016 010 844 A1. The pre-charging circuit there serves for pre-charging an intermediate circuit capacity of a DC intermediate circuit of an electric motor vehicle with electrical energy from a DC voltage source. This pre-charging circuit has a controllable switching unit for electrically coupling the DC voltage source to the DC intermediate circuit and a corresponding control unit. The switching unit comprises at least two electrical capacitors, a switching mechanism, a source-side main switch element for electrically coupling the switching mechanism to the DC voltage source and a DC intermediate circuit-side main switch element for electrically coupling the switching mechanism to the DC intermediate circuit. The switching mechanism has a plurality of controllable coupling switching elements connected to the capacitors and is designed to connect the capacitors in series or in parallel depending on the respective switching states of the coupling switching elements. This way, an improved pre-charging circuit or an improved operating method for a pre-charging circuit is to be implemented.

The object of the present invention is to enable efficient and component-friendly temporary parallel operation of a fuel cell system and a battery.

This object is achieved according to the invention by the subject matter of the independent patent claims. Possible refinements and further developments of the present invention are disclosed in the dependent claims, in the description, and in the figures.

The pre-charging switching device according to the invention serves, is thus designed or configured, for automatically adjusting an output voltage of a fuel cell system and a mains or battery voltage of a battery connected in parallel thereto, i.e., to the fuel cell system, during operation or in the intended installation position of the pre-charging switching device, with respect to an electrical load to be supplied without a DC-to-DC converter connected therebetween. The output voltage of the fuel cell system can be present or detected at an input connection of the pre-charging switching device, while the mains or battery voltage can be present at an output connection of the pre-charging switching device. This can apply in the intended installation position of the pre-charging switching device according to the invention in a corresponding electrical system. The pre-charging switching device according to the invention itself, however, can be, for example, a compact circuit or a compact component that can be designed and installed independently of the fuel cell system and the battery or the load. In the intended installation position, the pre-charging switching device can be connected between the fuel cell system and the battery, so that the load can be supplied by the battery alone or additionally or alternatively by the fuel cell system if it is switched on, i.e., is electrically integrated, via the pre-charging switching device. Likewise, the battery can then optionally be charged by the fuel cell system via the pre-charging switching device. The fuel cell system can then be connectable or connected to the battery solely via the pre-charging switching device as well as optionally corresponding connecting or supply lines, in particular without an DC-to-DC converter or the like connected therebetween.

The pre-charging switching device according to the invention can be deployed, for example, in a motor vehicle. The load can then be or comprise an on-board electrical system of the motor vehicle or an electrical apparatus connected thereto, such as an electric traction motor, a pump, an air conditioning device and/or the like. However, other applications or purposes of the present invention may also be possible.

As already indicated, the pre-charging switching device comprises the input connection for connecting the fuel cell system or an output of the fuel cell system to the pre-charging switching device and the output connection for electrically connecting the pre-charging switching device to the battery and the load. Further, the pre-charging switching device has an adjustment switching unit connected between the input connection and the output connection. This adjustment switching unit can in particular be manufactured or designed as a compact circuit or compact component, for example, as an integrated circuit or as a correspondingly equipped circuit board. The input connection and the output connection can also be arranged on this circuit board or this circuit or this component. The adjustment switching unit also has a controllable limiting element for limiting a current or a voltage increase when interconnecting the fuel cell system and the battery via the pre-charging switching device as well as a regulating device coupled thereto.

The adjustment switching unit or its regulating device is configured to—in comparison to a direct electrical connecting, for example, solely via an electromechanical switch without further parts or components-dampened adjustment of the voltages, i.e., the voltage of the fuel cell system applied on the input side during operation and the mains or Battery voltage applied on the output side, by automatically regulating a direct current carrying behavior of the limiting element. Specifically, the adjustment switching unit or its regulating device is configured to regulate the direct current carrying behavior of the limiting element depending on a fuel cell system current, i.e., an output current of the fuel cell system, detected or flowing in on the input side, i.e., at an input of the pre-charging switching device or the adjustment switching unit. By means of the adjustment switching unit or its regulating device, it can be regulated or set in particular whether and, optionally, how much direct current flows or can flow, in particular in the direction from the input connection to the output connection, through the pre-charging switching device or the controllable limiting element.

Thus, the regulating device regulates the direct current flow through the limiting element in order to carry out or achieve the damped voltage adjustment, which is also described here as regulating the limiting element. For this purpose, the pre-charging switching device can comprise a current measuring device, in particular connected or coupled to the regulating device, for continuously or regularly measuring the incoming fuel cell system current. Thus, this fuel cell system current can serve, i.e., be used, as at least one control variable for regulating the limiting element.

The limiting element can be a switch or a switching device or can comprise at least one switch or at least one switching device. The regulating device can control such a switch or switching device or can control it in a regulated manner. The regulating device can be configured to control or switch the switch or the switching device or the limiting element gradually or stepwise, i.e., little by little or over one or more intermediate steps or intermediate stages, from permanently open, i.e., blocked, to permanently and completely closed, i.e., permeable or conductive. This is done here depending on the current flowing through the input connection when the voltages are adjusted. This means that the voltages can be adjusted according to the situation and needs, for example, as slowly as necessary and as quickly as possible. This enables safe and at the same time particularly fast and efficient operation when connecting the fuel cell system and battery. By means of the present invention, the voltages can be adjusted easily and with little effort and a reduced component load can be achieved when connecting the fuel cell system and the battery.

In previous approaches, a step-up or step-down converter, i.e., a DC-to-DC converter, can be connected between the fuel cell system and the battery to electrically couple a fuel cell system to a battery. However, such a DC-to-DC converter means significantly increased complexity and correspondingly increased weight and cost. The elimination of such a DC-to-DC converter connected downstream of the fuel cell system, which is made possible by the present invention or provided for in the present invention, results in an advantage over conventional solutions in terms of complexity, weight and costs. At the moment of electrical interconnection of the fuel cell system and battery, the pre-charging switching device provided according to the invention can achieve here a damped adjustment of their voltages or voltage levels. Thus, the pre-charging switching device according to the invention can therefore be used to implement pre-charging of components of the fuel cell system and, for example, to avoid or dampen the occurrence of abrupt electrical load changes.

Alternatively, a direct interconnection of the fuel cell system and the battery could be provided. However, this results in restrictions with regard to an operating window of the fuel cell system, which can be avoided using the present invention. In practice, fuel cell modules of a fuel cell system have to date been equipped with their own protective diode, which ensures that a current can only flow from the output of the fuel cell system to the battery or the load and not in the opposite direction. Such protective diodes generate a corresponding thermal power loss, which is determined by the forward voltage 10 of the respective protective diode and must be dissipated in each fuel cell module. This can cause additional complexity, weight and costs. In addition, a common parts strategy cannot be easily implemented this way, since each fuel cell module must be manufactured individually with or without a protective diode depending on the electrical connection, i.e., the number of serial and parallel fuel cells. In particular, if only a temporary connection of the fuel cell system to the battery is provided, but also, for example, in the event of a failure of a fuel cell module or a module of the battery or the like, a simple interconnection, for example, by means of an electromechanical switch, can lead to abrupt, i.e., very steep-sided load and voltage jumps, which can affect the corresponding electrical system. This problem can be addressed by the present invention.

The present invention can be used for or in conjunction with almost any battery, for example, from backup batteries to full-fledged high-voltage traction batteries of an electric motor vehicle or the like. By means of the present invention, for example, a fuel cell range extender system can be implemented in a motor vehicle, which also has a battery and a fuel cell system connected in parallel with respect to a traction motor of the motor vehicle. For this purpose, the pre-charging switching device according to the invention can advantageously be combined with an interconnection device which enables flexible, modular interconnection of several fuel cell modules, i.e., the implementation or switching of different interconnections or interconnection configurations of the fuel cell system and, thus, different configurations or combinations of parallel and/or series interconnections of fuel cell modules or individual fuel cells.

In a possible embodiment of the present invention, the limiting element comprises a semiconductor transistor switch or is designed as such. The limiting element can be, for example, a N-FET or can comprise such. This means that the pre-charging switching device can also be designed entirely or partially as an integrated semiconductor circuit or can comprise such. Likewise, the pre-charging circuit can be or comprise, for example, a circuit board with several components arranged thereon, such as the limiting element designed as a semiconductor component, one or more SMDs (surface-mounted devices) and/or the like. The pre-charging switching device can, for example, comprise a housing in which the remaining parts or components of the pre-charging switching device can be arranged, for example, cast-in. A semiconductor transistor switch provided here can, for example, be switched more easily, more precisely and quickly and without the risk of spark erosion or contact erosion or the like in comparison to conventional electromechanical switches. In particular, a semiconductor transistor switch can be regulated in order to gradually adjust the direct current carrying behavior. This enables the damped adjustment of the voltages on both sides of the pre-charging switching device in a particularly simple, efficient and cost-effective manner.

In a further possible embodiment of the present invention, the adjustment switching unit, in particular its regulating device, is configured for linearly regulating the direct current carrying behavior of the limiting element. In particular, the adjustment switching unit or its regulating device can be configured for down-regulating an effective resistance of the limiting element during the adjustment or for dampened adjustments of the voltages. Such a linear regulation can be particularly easy to implement and can also avoid short-term current or voltage peaks.

In a further possible embodiment of the present invention, the adjustment switching unit, in particular its regulating device, is configured for PWM regulating (PWM: pulse width modulation) of the direct current carrying behavior of the limiting element. In particular, the adjustment switching unit or its regulating device can be configured for gradually increasing a pulse duty factor during the adjustment or for dampened adjustments of the voltages. Since with such a PWM regulation the limiting element is not controlled linearly, but rather operated in pulses, its power loss parabola can be passed through particularly quickly. This can result in or enable a correspondingly lower heating of the limiting element and, thus, an increased overall efficiency of the pre-charging switching device. For example, the pulse duty factor, i.e., a pulse-pause ratio, can be changed or increased in several predetermined steps or stages. A change to the next step can be carried out, for example, when a certain current flow or a certain voltage has been established and/or, for example, a predetermined minimum time has elapsed at the respective current step.

If the linear regulation of the limiting element has reached its maximum or the minimum resistance of the limiting element or if the pulse duty factor has reached 100% in the PWM regulation, the adjustment switching unit or its regulating device can then automatically switch on a bypass of the limiting element through a connection with less resistance between input connection and output connection of the pre-charging switching device. For this purpose, for example, a corresponding electromechanical switch or contactor can be automatically closed in a circuit or line branch parallel to the limiting element, which can be open during the regulated, damped adjustment. In this way, both the desired damped adjustment of the voltages and particularly low-loss and therefore particularly efficient operation after the adjustment can be made possible.

In a further possible embodiment of the present invention, the adjustment switching unit, in particular its regulating device, is configured to detect a respective current system state and to automatically adapt the regulation for adjusting the voltages depending on the detected system state. To detect or determine the system state, for example, a predetermined parameter or a predetermined size of at least one area, an assembly or a component of the pre-charging switching device, the fuel cell system and/or the battery can be measured or otherwise determined. For example, a respective current temperature can be measured. To adapt the regulation, for example, a time constant, which characterizes the adjustment of the voltages, can be set or varied. For example, a temperature of the system or a region thereof can influence parameters or properties of the system that can determine or change the time constant. For example, a resistance can also decrease as the temperature decreases, which can also reduce the time constant t according to τ=R·C. Such changes can be counteracted in order to set or maintain a predetermined or desired adjustment behavior. For this purpose, for example, an adaptable resistance of the pre-charging switching device or the adjustment switching unit, in particular, in the form of the regulated transistor or semiconductor transistor switch described elsewhere, can be varied or regulated accordingly—in the present example, for example, increased in order to counteract the lower temperature or compensate for its effect. As a result, a particularly robust and reliable constant or consistent behavior of the pre-charging switching device and, thus, a correspondingly robust and reliable operation of the system or network comprising the fuel cell system and the battery can be achieved, regardless of the respective system states or environmental conditions or over a particularly wide range of system states or environmental conditions.

In a further possible embodiment of the present invention, the pre-charging switching device has a main branch and a secondary branch that is connected in parallel thereto or extends electrically parallel thereto. A switch, in particular an electromechanical contactor, is arranged in each of the main branch and in the secondary branch, wherein the input connection can be connected respectively to the output connection in an electrically conductive manner by closing the contactor or wherein an electrical connection between the input connection and the output connection in the pre-charging switching device can be interrupted by opening the same. Here, the limiting element is arranged or connected electrically in series with the contactor in the secondary branch. The pre-charging circuit can be configured to close or switch on the limiting element—as described elsewhere—in a regulated manner to adjust the voltages and to close the contactor arranged in the main branch after the voltages have been adjusted. Before the start of regulating the limiting element, the contactor in the main branch is open or can be opened and the contactor in the secondary branch is closed or can be closed with the limiting element being open or blocked. After the voltages have been adjusted and the contactor in the main branch has been closed, the contactor in the secondary branch can then be automatically opened and, optionally, the limiting element can be opened or blocked. This would then result in a direct electrical connection between the input connection and the output connection with damped voltage adjustment and, thus, a corresponding direct electrical connection between the fuel cell system and the battery switched via the main branch during operation or in the intended installation position of the pre-charging switching device, which can be particularly of low-resistance by using of the contactor. This makes it possible to connect the fuel cell system and the battery with particularly low load, even without a voltage converter connected between the fuel cell system and the battery. This is the case because when the contactor in the main branch is closed and the contactor in the secondary branch is only opened afterwards, there, a conductive connection via the other branch and, thus, at least essentially the same voltage level on both sides of the contactor, so that voltage or spark erosion or contact erosion can be avoided or reduced when the contactors are respectively switched.

In a possible further development of the present invention, the contactors are designed to be bistable. In other words, the contactors can be or comprise, for example, bistable relays. This enables further improved efficiency, since energy only has to be used to switch the contactors, i.e., to change their switching state or position, but not to keep the contactors in a specific switching state or in a specific position. Thus, a correspondingly reduced energy consumption during operation of the pre-charging switching device, i.e., improved overall efficiency, can be achieved.

In a possible further development of the present invention, the pre-charging switching device has at least one failure circuit. This failure circuit comprises an energy storage of its own and is configured to automatically open at least one of the contactors with the help of the energy stored in the energy storage, when a supply to the at least one contactor fails—at least if it is not already in the open state. If, for example, an energy or voltage supply to the contactor or a corresponding switching device for switching the contactor is interrupted, the contactor can still be automatically and reliably put into the open and therefore electrically safe state by the failure circuit, independent of an external energy or voltage supply. This makes it possible to achieve improved safety of the pre-charging switching device or the system or network comprising the fuel cell system, the pre-charging switching device and the battery. The failure circuit can ensure that in an emergency, danger or damage situation, an HV off state can be assumed or established particularly reliably, i.e., a state in which a high-voltage supply to downstream components is switched off or interrupted. The energy storage can be designed, for example, as a capacitor, such as a double-layer capacitor or the like, or can comprise such a capacitor. For example, compared to using a battery or battery cell as energy storage for the failure circuit, this can enable the failure circuit to be reliably available for a longer period of time. Depending on the design or application, a battery or battery cell can also be used as an energy storage device for the failure circuit.

In a possible further development of the present invention, the pre-charging switching device has a dedicated inductance connected in series with the limiting element. An electrical or electronic component is therefore provided here, which serves as an inductance in the pre-charging switching device, in particular in the adjustment switching unit, so that not only unavoidable parasitic inductances of the other parts or components are used. By means of such an inductance, in particular connected in series upstream of the limiting element, an inductive portion of an overall impedance can be increased. If, as described elsewhere, a PWM regulation of the limiting element is provided, the inductance can function as a frequency-dependent resistor, for example, in combination with a basic frequency of the PWM regulation or a PWM signal for controlling the limiting element for adjusting the voltages that can be set by correspondingly regulating the pre-charging switching device or the limiting element. This means that steep-sided changes in the current flowing from the fuel cell system or the input connection of the pre-charging switching device can be dampened more strongly as a result of the pulse-shaped PWM control than would be the case simply due to the unavoidable parasitic capacitances or inductances that are present in the respective system or circuit combination. This means that current and/or voltage jumps, in particular abrupt or steep-edged ones, can be avoided or reduced by means of the pre-charging switching device, when the fuel cell system and the battery are interconnected. In a simple embodiment of the pre-charging switching device, for example, the contactor can be arranged in series in the main branch mentioned elsewhere and, in parallel thereto, the inductance, the limiting element and the contactor can be arranged in series in the secondary branch.

In a further possible embodiment of the present invention, the pre-charging switching device simulates the function or behavior of an ideal diode. In other words, the pre-charging circuit functionally forms an ideal diode—at least in addition to any other optionally intended functions. For this purpose, the pre-charging circuit can, for example, have a transistor and an associated regulating or control device, which is configured to implement the ideal diode function by means of appropriate control of the transistor. An ideal diode implemented in this way can, for example, have reduced power loss compared to a real elementary germanium or silicon diode and can, thus, further reduce the energy requirement of the pre-charging switching device, i.e., further improve its efficiency. A further advantage of the embodiment of the present invention proposed here lies in the outsourcing or central provision of the diode function in the pre-charging switching device. This means that the fuel cells or fuel cell modules of the fuel cell system connected or to be connected to the pre-charging switching device do not have to have or comprise their own corresponding protective diodes. Thus, especially when several fuel cells or fuel cell modules are connected in series, the total number of corresponding diodes or diode devices can be reduced compared to conventional fuel cell systems, since only one diode device or diode function has to be used for each provided parallel branch of fuel cells or fuel cell modules. The pre-charging switching device makes it possible to use various types of fuel cell systems or fuel cell modules particularly flexibly, regardless of whether they are equipped with an individual protective diode or not. The correspondingly possible simplified design of the fuel cell modules and the central accessibility of the pre-charging switching device can also enable simplified maintenance or repairs. Since the pre-charging switching device combines the functions of an ideal diode and the damped voltage adjustment already described, it can also be referred to as AID (adjustment of current and/or voltage in combination with an ideal diode).

In a possible further development of the present invention, the pre-charging switching device has a first semiconductor-based transistor switch, in particular arranged on the input side, and a second semiconductor-based transistor switch, in particular arranged on the output side, which are connected in series between the input connection and the output connection. Further, the pre-charging switching device here has a control device connected at least to the second transistor switch. The first transistor switch functions here as the limiting element and can therefore correspond to the corresponding semiconductor transistor switch mentioned elsewhere. The second transistor switch is connected opposite thereto and is controlled by the control device as an ideal diode during operation of the pre-charging switching device as intended. The fact that the two transistor switches are connected opposite to one another can mean, for example, that the input connection is connected to the drain of the first transistor switch, the source of the first transistor switch is connected to the source of the second transistor switch and the output connection is connected to the drain of the second transistor switch. The control device can measure a voltage or voltage difference occurring there at the gate and source of the second transistor switch and, depending on this, either switch the second transistor switch completely on or block it to block the current flow. In the manner described here, the functions mentioned for voltage adjustment and behavior as an ideal diode can be realized or implemented particularly easily, efficiently and cost-effectively.

In a further possible embodiment of the present invention, the pre-charging switching device has a bypass circuit for bypassing the limiting element with reduced resistance. This bypass circuit can, for example, comprise an electromechanical switch that can be closed for bypassing, i.e., to form a bypass that bypasses the limiting element. In the closed, i.e., connected, state, such a bypass has a lower electrical resistance than the limiting element in its closed, i.e., connected, state. The pre-charging circuit or the bypass circuit can be configured to bypass the limiting element, for example, to close the corresponding electromechanical switch or contactor after the limiting element or its regulation has reached the permanently and completely closed or switched on state. For example, the limiting element, as described, can be implemented as the semiconductor transistor switch or as the first transistor switch, while the bypass can be designed as or comprise an electromechanical switch or contactor. The limiting element then enables a particularly simple and precise regulation for adjusting the voltages, while the bypass can provide or form a particularly low-resistance and therefore particularly low-loss electrical connection between the input connection and the output connection of the pre-charging switching device after the voltages have been adjusted. This ultimately allows the overall efficiency of the pre-charging switching device to be further improved.

The bypass or the switch or contactor used therein can in particular be bistable. Such a bistable design or configuration of the bypass can save energy that would otherwise have to be used to keep the bypass circuit in the closed state. This can therefore further reduce the energy requirement of the pre-charging switching device and further improve the efficiency of the pre-charging switching device. The bypass circuit can-analogous to that described elsewhere-comprise a failure circuit or be coupled to one in order to ensure automatically opening the bypass or the switch or contactor provided therein in the event of failure or interruption of a power supply or supply voltage of the bypass circuit by means of its own energy storage or energy reserves. Accordingly, the bypass circuit can be implemented in a fail-safe and operationally safe manner, i.e., it can be configured to open automatically, that is to say to cancel the bypass, if the energy or voltage supply fails. A corresponding failure circuit can be connected to the bypass circuit or integrated into it. In the example described elsewhere, in which the pre-charging switching device comprises the first transistor switch as a limiting element and the second transistor switch connected opposite thereto for implementing the ideal diode function, the bypass circuit can in particular be configured for bypassing the first transistor switch only, but not for bypassing the second transistor switch. As a result, the risk of damage to the fuel cell system caused by a current flowing counter to the forward direction of the second transistor switch can be minimized.

In a further possible embodiment of the present invention, the pre-charging switching device comprises a galvanically isolating energy supply unit or energy supply circuit for supplying energy or voltage to the remaining components or parts of the pre-charging switching device. This can enable particularly safe and reliable operation of the pre-charging switching device. The energy supply unit can, for example, comprise a galvanically insulating DC-to-DC converter or galvanic insulation in order to enable simple control and supply of the remaining components of the pre-charging switching device even when, for example, they are deployed or operated in a high-voltage environment of the fuel cell system and the battery, which is designed, for example, as a high-voltage or traction battery.

The pre-charging switching device, in particular an integrated circuit or a semiconductor component comprised therein, can comprise or integrate further components or functions. For example, the pre-charging switching device can comprise a universal control through which further functions are realized or implemented or can be carried out. For example, the pre-charging switching device or the universal control can have or implement a gate control for implementing the ideal diode or ideal diode function by means of one or more transistors, the possibility of PWM or linear regulation of a transistor gate to represent a switch functionality, a control of a bipolar relay, such as bistable bypass, a current measurement, for example by means of a shunt and/or a Hall sensor, an over-current protection shutdown, an over-voltage protection shutdown, a configurability or configuration option via a bus connection or through appropriate IC external circuitry or via software in the flash process, a communication interface for communication with a higher-level control unit, for example via a bus connection, one or more interfaces for the external circuitry for configuration or programming, and/or the like. By means of such a combination or integration of functionalities or features in an integrated circuit or a compact switching device, a corresponding overall circuit and, thus, also the pre-charging switching device according to the invention could possibly be manufactured more cost-effectively than, for example, a printed circuit board or a combination of several printed boards on which some or all of the functionalities mentioned are implemented by separate components or assemblies. How individual, if applicable, the same or identically constructed, parts or components of the pre-charging switching device or the universal control behave—for example, as a bidirectional switch or as a diode device—can be determined or set, for example, by means of configuration or programming via a bus connection, via a flash process or by means of an external circuit, for example by means of a jumper, a solder bridge, a resistor circuit or a similar type of external circuit of the pre-charging switching device and/or the universal control.

A further aspect of the present invention is a fuel cell device which has several fuel cells and at least one output side pre-charging switching device according to the invention. The fuel cell device according to the invention can in particular comprise the fuel cell system mentioned in connection with the pre-charging switching device according to the invention. The multiple fuel cells can in particular be combined or organized into several fuel cell modules, each of which can comprise a stack of several individual fuel cells. In particular, several fuel cells or several fuel cell modules of the fuel cell device can be interconnected differently in order to deliver different output voltages or output currents. In particular, the fuel cell device can have a respective pre-charging switching device according to the invention for each parallel branch or parallel strand of fuel cells or fuel cell modules. The fuel cells or fuel cell modules of the fuel cell device can each internally have at least one, in particular at least two, decoupling switches, which is or are preferably designed as a bistable contactor. The decoupling switches serve or are configured to electrically isolate the respective fuel cell or the respective fuel cell module from the rest of the fuel cell device. By opening the decoupling switch, the respective fuel cell or the respective fuel cell module can be decoupled from an electrical circuitry network of the fuel cell device. The decoupling switches can also be useful if a bypass or bridging is provided for the respective fuel cell or the respective fuel cell module, for example, in the form of corresponding bypass switches, since then by opening the at least one internal decoupling switch of the respective fuel cell or the respective fuel cell module a defined electrical behavior of the respective parallel branch, in particular of the respective bypass, can be ensured.

Several fuel cell modules of the fuel cell device according to the invention can have different numbers of fuel cells. In other words, the fuel cell device can therefore comprise at least two, preferably several, fuel cell modules that have different numbers of internal individual fuel cells. This means that the correspondingly different fuel cell modules can provide different output voltages or voltage levels. This opens up, particularly in combination with the possibility of setting different interconnections of the fuel cell modules using a corresponding interconnection device or circuit control, an even greater flexibility or range of interconnections and a correspondingly particularly broad range of settings or uses of the fuel cell device. For example, it can be ensured particularly reliably in this way that a battery coupled to the fuel cell device can be supplied with energy, i.e., charged, by the fuel cell device over its entire range of the state of charge by adapting or setting the output voltage of the fuel cell device through appropriate selection and interconnection of the different fuel cell modules depending on the current charge state of the battery.

The fuel cell modules of the fuel cell device can be interconnected or can be interconnectable in several parallel branches, each of which can comprise several fuel cell modules interconnected in series with different numbers of fuel cells. The fuel cell modules can be arranged in different parallel branches in the direction of the series interconnection in different orders with regard to their numbers of fuel cells or can be interconnected when the corresponding series connections are implemented. The various parallel branches of the fuel cell device can comprise the same number of fuel cells overall. For example, two parallel branches can each comprise a fuel cell module with a fuel cell number A, a fuel cell module with a fuel cell number B and a fuel cell module with a fuel cell number C, wherein A, B and C are different integers. In one parallel branch, these fuel cell modules can then be arranged or interconnected in series in the sequence A, B, C and in the other parallel branch, for example, in the sequence C, A, B. As a result, a particularly large number of different interconnections or output voltages of the fuel cell device can be implemented particularly easily and effectively, for example, by using the interconnection device mentioned or respective bypasses or bypass switches. The interconnection device or respective bypasses or bypass switches can in particular be arranged in such a way that those fuel cell modules from all parallel branches that have the largest number of fuel cells within their respective parallel branch can all be connected in series between an input and an output of the fuel cell device. The same can apply to the fuel cell modules with the smallest number of fuel cells in their respective parallel branch. In this way, a particularly wide range of output voltages of the fuel cell device that can be set using respective interconnections can be implemented. It is also possible for different parallel branches to each have a different number of fuel cells overall, for example, through different numbers and/or different designs of the fuel cell modules.

In the present sense, a parallel branch describes an electrical path or circuit branch that is connected or switchable in parallel to other corresponding branches or paths, that is to say to other parallel branches, with respect to external contacts or outer connections of the fuel cell device. Such a parallel branch of the fuel cell device can each comprise several fuel cell modules connected in series. These can be parallel branches that are actually connected in a specific application, i.e., in a specific fuel cell device or a specific application of the present invention, or can be switched or adjusted by means of the interconnection device and/or the bypasses or bypass switches.

If several parallel branches of fuel cells or fuel cell modules are provided or can be switched, a pre-charging switching device according to the invention can be provided or arranged or switched for each parallel branch. Likewise, a single or common pre-charging switching device can be provided for several or all parallel branches, which can then be arranged in a current or line path that brings together the corresponding parallel branches on an input side of the pre-charging switching device.

A further aspect of the present invention is a motor vehicle which has a fuel cell device according to the invention and a battery for supplying an electrical load of the motor vehicle. The fuel cell device and the battery are connected in parallel to one another with respect to the electrical load without an DC-to-DC converter connected therebetween. In other words, the motor vehicle has an electrical load, a fuel cell system and a battery connected in parallel with respect to the load, wherein a pre-charging switching device according to the invention is connected between an output of the fuel cell system and a node to which a side of the battery and an input of the load are connected. The pre-charging switching device can thus enable or cause a dampened adjustment of the output voltage of the fuel cell system and the battery voltage or the mains voltage present at the node when the fuel cell system is switched on to supply energy to the load and/or to charge the battery.

A switch or contactor, also referred to here as an input contactor, can be arranged or connected between an input of the fuel cell system on the one hand and an output of the load as well as the other side of the battery on the other hand. Thus, in combination with the pre-charging switching device, the fuel cell system can be completely separated from the battery and the load, i.e., a corresponding part of an on-board electrical system of the motor vehicle. This can enable improved safety and a further minimization of electrical losses, for example, due to leakage currents or the like.

By means of the described components of the motor vehicle according to the invention, for example, a fuel cell-based range extender drive system of the motor vehicle can be implemented. For this purpose, the battery can be a high-voltage traction battery which, for example, can have a maximum or nominal voltage of several 100 V, for example, 200 V or 400 V or 800 V or more, and a capacity of several dozen kilowatt hours, for example, at least 30 kWh, at least 50 kWh, at least 60 kWh, at least 70 kWh or more. The battery can also be, for example, a smaller buffer battery or the like.

The electrical load of the motor vehicle can be, for example, an on-board electrical system, electrical components or apparatus connected to it, an electric traction motor and/or the like.

The motor vehicle according to the invention can in particular be the motor vehicle mentioned in connection with the pre-charging switching device according to the invention and/or the fuel cell device according to the invention and can accordingly have some or all of the properties and/or features mentioned there. Such an electric motor vehicle represents a particularly useful application of the present invention, since, on the one hand, electrical loads or performance requirements can vary particularly strongly and quickly during driving operation and, on the other hand, a reduction in weight, components and complexity—for example, by dispensing with the DC-to-DC converter that was to date usually provided—can have a direct positive effect on the efficiency, range and sustainability of the motor vehicle.

Further features of the invention can result from the following description of the figures and from the drawing. The features and combinations of features mentioned above in the description as well as the features and combinations of features shown below in the description of the figures and/or in the figures alone can be used not only in the combination specified in each case, but also in other combinations or on their own, without departing from the scope of the invention.

The drawing shows in:

FIG. 1 a schematic representation of a motor vehicle with a fuel cell device, a battery connected in parallel thereto, and a coupling pre-charging circuit in a first variant;

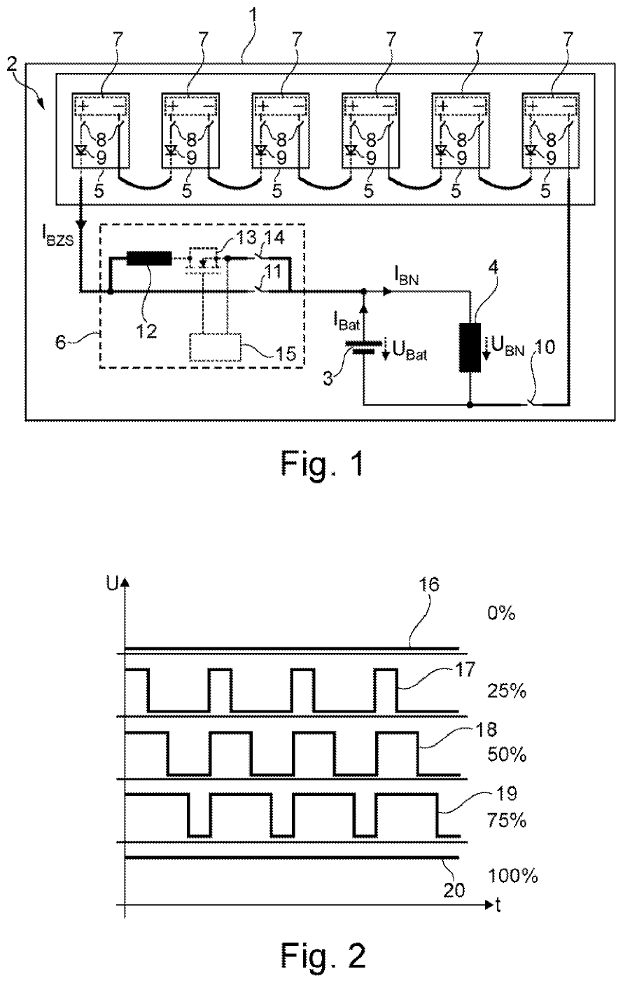

FIG. 2 a schematic diagram representation to illustrate a control of the pre-charging circuit;

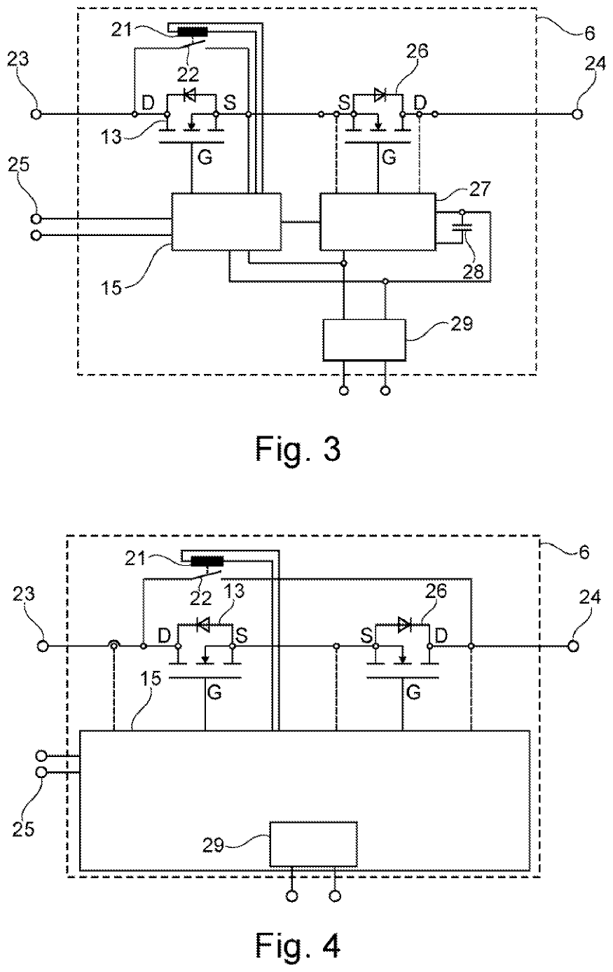

FIG. 3 a partial schematic representation of the pre-charging circuit in a second variant;

FIG. 4 a partial schematic representation of the pre-charging circuit in a third variant; and

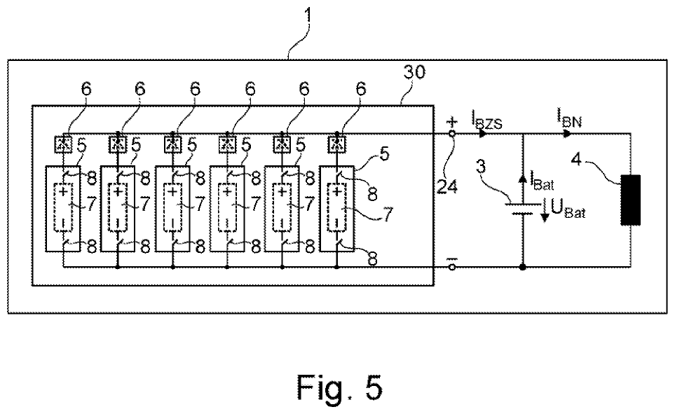

FIG. 5 a schematic representation of the motor vehicle with a fuel cell device with several pre-charging circuits.

Identical or functionally identical elements are provided with the same reference signs in the figures.

Fuel cell devices, for example, for vehicles, can comprise stacks of several fuel cells and, thus, a corresponding number of bipolar plates. A total voltage UBZS generated or output by such a fuel cell device is then composed of the sum of the cell voltages UZ of the individual fuel cells. In order for a fuel cell device to deliver its energy to a load or an energy storage device, certain requirements must be met. Especially in a vehicle, electrical energy consumption can be very dynamic, which means that either the fuel cell device has to meet the corresponding highly dynamic performance requirements through a correspondingly highly dynamic tracking of the media hydrogen and oxygen or that at least a part, in particular a large part, of a corresponding dynamic must be absorbed by a buffer storage, for example, a high-voltage or traction battery of the vehicle. In the case of a corresponding combined system of fuel cells and a traction battery in a vehicle, one can then speak of a fuel cell range extender, in particular if a total contribution of a battery capacity of the traction battery to the range of the vehicle is at least in the range of the range gained by the fuel cell device. However, with such a combined system there is the challenge of coupling the fuel cell device, the traction battery and the vehicles electrical loads.

In order to omit a complex and expensive DC-to-DC converter, which converts the voltage UBZS of the fuel cell device, in principle, a direct connection of the fuel cell device and the traction battery can be considered. However, this can result in restrictions regarding the operating window of the fuel cell device. If the fuel cell device and traction battery are electrically connected in parallel, an operating point will be established on the polarization curve of the fuel cell device, which will be defined by the resulting voltage. This is called voltage controlled operation. Corresponding to such an operating point, a maximum electrical power that can be delivered to the traction battery by the fuel cell device is established. This power can vary depending on the state of charge of the traction battery, wherein electrical power can possibly only be delivered from the fuel cell device to the traction battery in a limited range or window of the state of charge, for example, between 45% and 100% of the state of charge.

Against this background, FIG. 1 shows a partial schematic representation of a motor vehicle 1, which is equipped with a fuel cell system 2 and a battery 3, which together provide electrical energy to supply a load 4 of the motor vehicle 1. The fuel cell system 2 can provide a fuel cell current I_{BZS} and the battery 3 can provide a battery current I_{Bat} with its battery voltage U_{Bat}, which results in an on-board electrical system current I_{BN}. Here, U_{BN} refers to an on-board electrical system voltage in a respective on-board electrical system of the motor vehicle 1.

The fuel cell system 2 comprises several fuel cell modules 5. At a first connection of the fuel cell system 2, a pre-charging switching device 6 is connected between it as well as the battery 3 and the load 4.

The fuel cell modules 5 can each comprise a fuel cell stack 7 made up of several individual fuel cells connected in series as well as input side and output side decoupling switches 8. For example, the decoupling switches 8 can be implemented as contactors, in particular as bistable contactors. Further, diode devices 9 are provided here, which can ensure that the fuel cell current I_{BZS} flows exclusively in the direction from the fuel cell system 2 into the battery 3 or to the load 4 in order to avoid damage to the fuel cell stack 7. In a simple case, the diode devices 9 can be implemented, for example, by Schottky diodes, which have a lower forward voltage compared to germanium or silicon diodes and, thus, have or can require lower power loss and comparatively lower cooling effort associated therewith.

An all-pole disconnection option is provided at a second or the other connection of the fuel cell system 2, which is referred to here as input contactor 10. This allows the fuel cell system 2 to be separated from the load 4 and the battery 3.

On the other side of the load 4 and the battery 3, the pre-charging switching device 6 has a main contactor 11 in a main branch for all-pole disconnection or decoupling of the output side of the fuel cell system 2 from the on-board electrical system, i.e., the battery 3 and the load 4. By closing the input contactor 10 and the main contactor 11, the fuel cell system 2 and the battery 3 can be connected together. However, the fuel cell system 2 and the battery 3 can have different voltage situations or voltage levels, wherein a voltage level on the output side of the pre-charging switching device 6, i.e., at a node between the pre-charging switching device 6, the battery 3 and the load 4, can also be influenced by a behavior or a load requirement of the load 4. Thus, a dampened adjustment of the voltages or voltage levels on both sides of the pre-charging switching device 6 can be favourable when interconnecting the fuel cell system 2 with the rest of the vehicle electrical system, in particular with the battery 3.

Such a damped adjustment is made possible here by the pre-charging switching device 6, which can therefore also be referred to as an adjustment circuit. The pre-charging switching device 6 is to be understood here in particular as a component or an assembly which is constructed as compactly as possible, so that the pre-charging switching device 6 can, for example, be particularly easily plugged in and/or screwed therewith or similarly attached to, in an electrically conductive and mechanically stable manner, a mounting plate, a mounting block or a three-dimensional mounting device.

In the example represented here, the pre-charging switching device 6 has a serial connection consisting of an inductance 12, a first transistor 13 and a secondary contactor 14 in parallel to the main branch in order to implement the damped voltage adjustment. In addition, the pre-charging switching device 6 comprises a regulating device 15 for regulating or controlling the first transistor 13 in a regulated manner. The first transistor 13, which is regulated by the regulating device 15 with regard to its direct current carrying behavior, functions here—in particular in combination with the inductance 12—as a limiting element.

To interconnect the fuel cell system 2 and the battery 3, the input contactor 10 and the secondary contactor 14 can be closed when the main contactor 11 is open and the first transistor 13 is open or blocked. The regulating device 15 can then, for example, as part of a linear regulation or a PWM regulation, gradually reduce the resistance of the first transistor 13 or gradually regulate the first transistor 13 up to a maximum conductivity or permeability, i.e., a maximum direct current carrying capability. The inductor 12 is optional and can, particularly, when using or implementing PWM regulation, represent a possibility of increasing the frequency dependence of the overall resistance or overall behavior of the pre-charging switching device 6. This can then enable improved, more precise or simplified regulation via pulse width modulation and the fundamental frequency thereof. In particular, when using or implementing a linear regulation, the inductance 12 can be cut down, i.e., omitted. For the regulation, the fuel cell current I_{BZS} entering the pre-charging switching device 6 on the input side, i.e., on the side facing the fuel cell system 2, or a fuel cell voltage, i.e., a voltage of the fuel cell system 2, can be used as a controlled variable in comparison or in relation to the battery voltage U_{Bat}. The fuel cell current I_{BZS} can be measured, for example, by a current measuring device, not shown in detail here, which can provide a corresponding measured value to the regulating device 15. If the regulating device 15 has regulated the first transistor 13 to maximum permeability, it is optional to wait for a predetermined adjustment time, the optimal length of which can be established or determined, for example, experimentally or based on a model. The main contactor 11 can then be closed in order to establish a lower-resistance connection of the fuel cell system 2 to the on-board electrical system or to the battery 3 and the load 4. Subsequently, to avoid losses, the secondary contactor 14 can be opened and, if optionally, the first transistor 13 can be blocked by the regulating device 15 in preparation for a later reconnection of the fuel cell system 2 with the battery 3.

Some or all of the switches or contactors used can be bistable and/or can be configured to open automatically in the event of a respective energy supply or operating voltage failure. This means that reduced energy consumption, i.e., increased efficiency, can be achieved without restricting safety, since the coils of the switches or contactors or corresponding relays do not have to be permanently energized in order to maintain a certain switching state.

The motor vehicle 1 or its electrical system represented schematically in sections here, in particular the fuel cell system 2, can have further parts or components not represented in detail here, such as seals, a gas diffusion system, coated membranes, electronics, an air compressor, valve, actuator, and sensor technology and/or and the like.

As part of the PWM regulation of the first transistor 13 by the regulating device 15, a gate-source path of the first transistor 13 can be supplied with a PWM signal generated by the regulating device 15. With such a PWM regulation of the first transistor 13, it is not regulated linearly, but rather operated in a pulsed manner. The pulse duty factor or a pulse-pause ratio, i.e., a temporal portion of an ongoing operating time at which the first transistor is closed, i.e., switched on and, thus, conductive, can be increased, in particular based on or starting from about 0%, until a value of 100% is reached, which means that the first transistor 13 then switches on permanently and completely. For this purpose, FIG. 2 shows a schematic diagram representation in which a PWM regulation of the first transistor 13 is illustrated. However, continuous regulation is also possible. In the represented diagram for PWM regulation, a voltage U is plotted against time t, wherein five voltage or PWM signals are shown that are present at different times and that are set or switched one after the other during the voltage adjustment. Initially, i.e., when or immediately after the secondary contactor 14 closes, the first transistor 13 is activated with a first PWM signal 16. By doing so, the first transistor 13 is permanently blocked, corresponding to a pulse duty factor, i.e., a pulse-pause ratio, of 0%. The first transistor 13 is then controlled with a second PWM signal 17 with a pulse-pause ratio of 25%. In a corresponding manner, the first transistor 13 is then gradually controlled with a third PWM signal 18 with a pulse-pause ratio of 50% and then with a fourth PWM signal 19 with a pulse-pause ratio of 75% and finally with a fifth PWM signal with a pulse-to-space ratio of 100%, so that it is then fully switched on. A change from one PWM signal or pulse-pause ratio to the next can be carried out in accordance with the regulation after a predetermined period of time or after a period of time that results depending on the fuel cell current I_{BZS} that sets in. The specific pulse-pause ratios represented here are only to be understood as examples. Other pulse-pause ratios can also be used or set.

When controlling or regulating the first transistor 13 with the PWM signals 17, 18, 19 represented, relatively rapid current changes can result due to their steep edge, which can be dampened by the upstream inductance 12 in order to reduce the load on the components.

The diode devices 9, individually represented in each of the fuel cell modules 5 in FIG. 1, in particular in their form or functionality as an ideal diode, and the pre-charging switching device 6 can be implemented or combined in a circuit or assembly that can be at least partially manufactured using semiconductor technology or as an integrated circuit. For this purpose, FIG. 3 shows a partial schematic representation of the pre-charging switching device 6 in a corresponding variant. Here, the regulating device 15 can be connected to a gate G of the first transistor 13 for the PWM regulation of the first transistor 13 and can provide or detect a gate reference potential at the source S of the first transistor 13. Moreover, a bypass relay 21, which can also be controlled or switched by the regulating device 15, is provided here and can bypass the first transistor 13 from its drain and source side with a connection of comparable lower resistance or loss. The bypass relay 21 can in particular be designed to be bistable in order to save energy by using a coil that, due to its principle, cannot be permanently energized. The regulating device 15 can automatically close the bypass relay 21 to bypass the first transistor 13 or control it to close corresponding bypass contacts 22, when the first transistor 13 has reached the pulse duty factor or a pulse-pause ratio of 100% during or after the voltage adjustment. As a result, losses that otherwise arise due to the small but still existing contact resistance of the fully switched-on first transistor 13 can be avoided or reduced.

The fuel cell current I_{BZS} can flow to the drain D of the first transistor 13 via an input connection 23 of the pre-charging switching device 6. A corresponding output current of the first transistor 13 can flow from its source S to an output connection 24 of the pre-charging switching device 6.

To control the pre-charging switching device 6 or the regulating device 15 as well as for any communication or data transmission with or from a higher-level host system or a higher-level control unit, for example, a regulating device or electronics of the motor vehicle 1, a bus connection 25 is provided here, for example. This can in particular be galvanically isolated, for example, opto-decoupled.

The pre-charging switching device 6 further comprises a second transistor 36, which is controlled or operated by a diode control 27 to implement the ideal diode function. The diode control 27 can be based on or comprise a component or a circuit that is designed to implement an ideal diode by controlling the second transistor 26—for example, a field effect transistor. Since such an part or circuit can contain a charge pump, a capacitor 28 is also indicated here. For example, an integrated circuit of the type LM74700-Q1, which was designed for the automotive manufacturing environment, can be used for or as the diode control 27. The diode control 27 can measure a voltage difference occurring there at the gate G and the source S of the second transistor 26 and either switch the second transistor 26 completely on or block a current flow through the second transistor 26.

Further, the pre-charging switching device 6 can comprise a galvanically insulating DC-to-DC converter or a galvanic insulation, referred to here as galvanic isolation 29, in order to enable simple control and supply of the components described even when they are deployed or operated in the high-voltage environment of the fuel cell system 2 and the battery 3. The galvanic isolation 29 can be, for example, a galvanically isolated or galvanically isolating circuit for supplying energy to the remaining components of the pre-charging switching device 6.

As described here, the pre-charging switching device 6 can combine the function of an ideal diode and the function for dampened adjustment of the voltages of the fuel cell system 2 and the battery 3 or the battery and load-side on-board electrical system and can therefore also be referred to as AID.

The pre-charging switching device 6 is to be understood here as a component or an assembly, for example, on a single circuit board or in a single common housing, which can be constructed as compactly as possible, so that it can be plugged in, screwed therewith or similarly attached in an electrically conductive and mechanically stable manner to, for example, a mounting plate explained in more detail elsewhere, a mounting block or a three-dimensional assembly device or the like. This means that the diode devices 9 can then be removed from the fuel cell modules 5 and deployed or arranged particularly easily and flexibly for different interconnections or configurations of the fuel cell modules 5 or the fuel cell system 2.

The use of semiconductor switches, i.e., of the first transistor 13 and the second transistor 26, proposed here, for example, instead of conventional electromechanical switches, can at least almost completely avoid wear of switching contacts that occurs with electromechanical switches, whereby the service life and robustness can be improved. In addition, the semiconductor switches or transistors 13, 26 enable controllable or gradual, i.e., somewhat gradual switching, in contrast to sudden or abrupt switching with electromechanical switches. This can also have a positive effect on the service life of the entire system and facilitate pre-control of the connections or material connections in the pre-charging switching device 6.

The potential disadvantage of the semiconductor switches, that they can have a higher electrical resistance than a conventional electromechanical switch even when switched on, i.e., closed, can be compensated for or minimized at least in part by the bypass relay 21. Such a bypass relay 21 can-unlike what is represented here-optionally also be provided for bypassing the second transistor 26 and then, for example, be controlled or switched by the regulating device 15 or the diode control 27. Here, a semiconductor switch or transistor can be combined with an electromechanical switch, wherein the latter can only being closed or maintained closed when the semiconductor switch or transistor has reached its fully switched on state, i.e., its maximum electrical conductivity. This means that contact resistance can be minimized at a corresponding point or route. When the corresponding electromechanical switch is closed in this way, here, for example, the bypass relay 21 or an electromechanical switch actuated by it, with the semiconductor switch or transistor switched on, the wear mentioned on the switching contacts of the electromechanical switch can also be minimized, since between the two sides of the semiconductor switch or transistor bypassed by the electromechanical switch no significant voltage drop occurs any more, i.e., there is no significant voltage difference. When opening, i.e., disconnecting or interrupting, the corresponding connection or route, the electromechanical switch can first be opened in the reverse order in order to minimize wear, i.e., contact erosion, and then the semiconductor switch or transistor can be opened or blocked completely or partially.

Based on or with respect to the variant of the pre-charging switching device 6 represented in FIG. 3, further functional integration is possible. For this purpose, FIG. 4 shows in sections and schematic another variant of the pre-charging switching device 6. This is basically constructed similarly to the variant represented in FIG. 3. However, in contrast thereto, other or further functions are here integrated into the regulating device 15. The regulating device 15 can be implemented, for example, as integrated circuit, through which the gate control for the first transistor 13 and the second transistor 26, the control of the bypass relay 21 and a provision or tapping of a gate reference potential between the transistors 13, 26 as well as connections for the bus connection 25 and a, in particular potential-free, power supply via the galvanic isolation 29 can be implemented.

The regulating device 15 can function as a universal control and can be designed as an integrated circuit. By the regulating device 15, the gate control for the first transistor 13 and the second transistor 26, the relay control of the at least one bypass relay 21 and a provision or tapping of a gate reference potential between the transistors 13, 36 as well as connections for the bus connection 25 and a, in particular potential-free, power supply via the galvanic isolation 29 can be implemented.

Here, a current and voltage measurement input are provided before bypassing the first transistor 13, its linear or PWM-based gate control, the relay control for the bypass relay 21, the gate reference potential or a corresponding measurement input between the transistors 13, 26, the linear or PWM-based gate control of the second transistor 26 and a voltage measuring input arranged downstream of it, i.e., arranged on the output side of it. Therefore, the regulating device 15 can have or integrate, for example, the following functionalities: gate control to implement an ideal diode by using transistors, the possibility of linear or PWM regulation of at least one gate for mapping a switch functionality, control of a bipolar relay, current measurement, in particular by means of a Shunt and/or Hall sensor, over-current protection shutdown, over-voltage protection shutdown, configurability via software in the flash method or through appropriate external wiring or via bus via the bus connection 25 and communication with a higher-level control unit via a corresponding communication interface and/or the bus connection 25. Likewise, further interfaces for external wiring, for programming and/or configuration can be provided, i.e., integrated into the regulating device 15 or the pre-charging switching device 6. Some or all of the functionalities mentioned can therefore be integrated in an integrated circuit configured for this purpose, which can form the regulating device 15 or be part of it. This can enable a particularly cost-effective implementation of the various functionalities or a corresponding overall circuit, for example, in comparison to implementation using separate components.

FIG. 5 shows a further partial schematic representation of the motor vehicle 1. The motor vehicle 1 here has-similar to what is already represented in FIG. 1—the battery 3 and several fuel cell modules 5 for supplying the load 4. Here, however, the fuel cell modules 5 are combined in a fuel cell device 30. In the fuel cell device 30, the fuel cell modules 5 are arranged in several, here for example six, parallel branches. Each of these parallel branches comprises, by way of example and for the sake of clarity, a fuel cell module 5, but can also comprise several fuel cell modules 5 connected in series. On the output side, a pre-charging switching device 6 is arranged in each of the parallel branches. As described, the pre-charging switching devices 6 can each function as an ideal diode and serve or be configured to regulate a respective current through the respective parallel branch. Thus, a corresponding protective diode no longer needs to be provided in the individual fuel cell modules 5 themselves, since the corresponding functionality is outsourced to the pre-charging switching devices 6.

Due to the realisation or implementation as described here, a particularly simple, effective, efficient and flexible combination of a fuel cell system 2 and the battery 3 in a directly connected parallel interconnection to supply an electrical load 4, can be implemented. Overall, the examples described show a system and a method for the low-loss, regulated electrical coupling of fuel cells and their controlled or regulated coupling to a battery device, for example, for an electric vehicle.

### LIST OF REFERENCE NUMERALS

1 motor vehicle
2 fuel cell system
3 battery
4 load
5 fuel cell module
6 pre-charging switching device
7 fuel cell stack
8 decoupling switch
9 diode device
10 input contactor
11 main contactor
12 inductance
13 first transistor
14 secondary contactor
15 regulating device
16 first PWM signal
17 second PWM signal
18 third PWM signal
19 fourth PWM signal
20 fifth PWM signal
21 bypass relay
22 bypass contacts
23 input connection
24 output connection
25 bus connection
26 second transistor
27 diode control
28 capacitor
29 galvanic isolation
30 fuel cell device
D drain
G gate
S source
I_{BZS} fuel cell current
I_{BN} on-board electrical system current
I_{Bat} battery current
U_{Bat} battery voltage
U_{BN} on-board electrical system voltage
t time

1. A pre-charging switching device for automatically adjusting an output voltage of a fuel cell system and a battery voltage of a battery connected in parallel with respect to a load to be supplied without a DC-to-DC converter connected therebetween, comprising an input connection for connecting the fuel cell system, an output connection for connecting to the battery and the load and an adjustment switching unit connected therebetween, wherein the adjustment switching unit has a controllable limiting element and a regulating device coupled thereto and is configured for damped adjustment of the voltages by regulating a direct current carrying behavior of the limiting element depending on a fuel cell system current detected on the input side,
wherein
the pre-charging switching device simulates the function of an ideal diode and, for this purpose, has a first transistor switch and a second transistor switch, which are connected in series between the input connection and the output connection, as well as a control device connected to the second transistor switch, wherein the first transistor switch functions as the limiting element and the second transistor switch is connected opposite thereto and is controlled as an ideal diode by the control device during operation of the pre-charging switching device as intended.

2. The pre-charging switching device according to claim 1,
wherein
the limiting element comprises a semiconductor transistor switch.

3. The pre-charging switching device according to claim 1,
wherein
the adjustment switching unit is configured for linearly regulating the direct current carrying behavior of the limiting element.

4. The pre-charging switching device according to claim 1,
wherein
the adjustment switching unit is configured for PWM regulating of the direct current carrying behavior of the limiting element.

5. The pre-charging switching device according to claim 1,
wherein
the adjustment switching unit is configured to detect a respective current system state and to automatically adapt the regulation for adjusting the voltages depending on the detected system state.

6. The pre-charging switching device according to claim 1,
wherein
the pre-charging switching device has a main branch and a secondary branch extending electrically parallel thereto, wherein a contactor is arranged in each of the main branch and the secondary branch, wherein the input connection can be connected to the output connection in an electrically conductive manner by closing the contactor, and wherein the limiting element in the secondary branch is arranged electrically in series with the contactor there.

7. The pre-charging switching device according to claim 6,
wherein
the contactors are bistable.

8. The pre-charging switching device according to claim 6,
wherein
the pre-charging switching device has at least one failure circuit, which comprises an energy storage of its own and is configured to automatically open at least one of the contactors with the help of the energy stored in the energy storage, when a supply to the at least one contactor fails.

9. The pre-charging switching device according to claim 6,
wherein
pre-charging switching device has a dedicated inductance connected in series with the limiting element.

10-11. (canceled)

12. The pre-charging switching device according to claim 1,
wherein
the pre-charging switching device has a bypass circuit for bypassing the limiting element with reduced resistance.

13. The pre-charging switching device according to claim 1,
wherein
the pre-charging switching device comprises a galvanically isolating energy supply unit for supplying energy to the remaining components of the pre-charging switching device.

14. A fuel cell device, comprising a plurality of fuel cells and at least one output side pre-charging switching device according to claim 1.

15. A motor vehicle comprising a fuel cell device according to claim 14 and a battery for supplying an electrical load of the motor vehicle, wherein the fuel cell device and the battery are connected in parallel to one another with respect to the electrical load without a DC-to-DC converter connected therebetween.

16. The pre-charging switching device according to claim 3,
wherein
the adjustment switching unit is configured for down-regulating a resistance of the limiting element.

17. The pre-charging switching device according to claim 4,
wherein
the adjustment switching unit is configured for gradually increasing a pulse duty factor.

18. The pre-charging switching device according to claim 5,
wherein
the adjustment switching unit is configured to detect a respective current temperature and to automatically adapt the regulation for adjusting the voltages depending on the detected current temperature.

19. A fuel cell device according to claim 14,
wherein
the at least one output side pre-charging switching device comprises one output side pre-charging switching device for each parallel branch of fuel cells.
